(19) United States
(12) Patent Application Publication
(10) Pub. No.: US 2015/0129926 A1
(43) Pub. Date: May 14, 2015

(54) SEMICONDUCTOR DEVICE AND MANUFACTURING METHOD THEREOF

(71) Applicant: SEMICONDUCTOR MANUFACTURING INTERNATIONAL (SHANGHAI) CORPORATION, Shanghai (CN)

(72) Inventor: De Yuan XIAO, Shanghai (CN)

(73) Assignee: SEMICONDUCTOR MANUFACTURING INTERNATIONAL (SHANGHAI) CORPORATION, Shanghai (CN)

(21) Appl. No.: 14/181,189

(22) Filed: Feb. 14, 2014

(30) Foreign Application Priority Data
Nov. 12, 2013 (CN) 201310562469.X

(51) Int. Cl. H01L 29/66; H01L 29/205; H01L 29/778

(52) U.S. Cl. CPC H01L 29/66977; H01L 29/7786; H01L 29/66431; H01L 29/205
USPC 257/105; 438/285

(57) ABSTRACT

A field effect transistor is provided. The field effect transistor includes a semiconductor region formed on a substrate, wherein the semiconductor region comprises an undoped channel region, a source region including a first dopant type, and a drain region including a second dopant type, and wherein the channel region is formed of a group III-V compound semiconductor material. The field effect transistor further includes a high-K gate formed on the channel region, wherein the high-K gate is configured to generate electron tunneling between the source region and the drain region when a gate voltage is applied, and wherein a first contact surface between the source region and the channel region and a second contact surface between the drain region and the channel region are inclined.

### CROSS-REFERENCE TO RELATED APPLICATIONS

This application claims priority to Chinese Patent Application No. 201310562469.X filed on Nov. 12, 2013, the disclosure of which is incorporated herein by reference in its entirety.

### BACKGROUND

1. Technical Field

The present disclosure relates to a field effect transistor, a semiconductor device including the field effect transistor, and a method of manufacturing the same. More particularly, the present disclosure relates to a Tunneling Field Effect Transistor (TFET).

2. Description of the Related Art

Advances in VLSI (Very Large Scale Integration) technology have enabled the density and performance of semiconductor devices, such as CMOS (Complementary Metal Oxide Semiconductor) devices, to scale in accordance with Moore's Law.

However, further miniaturization of semiconductor devices poses scaling challenges in chip power consumption and power density. For example, the power density increases when the size of the CMOS is reduced (since a greater number of CMOSs can be fabricated on a chip). Additionally, the chip power consumption increases due to leakage current caused by short channel effect. To compensate for the leakage current, the power supply voltage (VDD) may need to be increased. In some instances, the power supply voltage may exceed the 5V standard operating voltage for current CMOS devices. Accordingly, it is necessary to suppress the leakage current and reduce the power supply voltage for the CMOS devices.

It has been suggested that significant savings in power consumption can be obtained by using low-voltage TFETs in place of conventional MOSFETs (Metal Oxide Semiconductor Field Effect Transistors) in logic circuits. TFETs are based on band-to-band tunneling. Specifically, TFETs switch by modulating quantum tunneling through a barrier instead of modulating thermionic emission over a barrier as in conventional MOSFETs. Therefore, TFETs are not limited by the thermal Maxwell-Boltzmann tail of carriers, which limits the subthreshold voltage of conventional MOSFETs to 60 mV/dec at room temperature (the subthreshold voltage corresponds to the minimum voltage required to drive the MOSFET to an ON state). Since TFETs have no short channel effect and can realize a high ON/OFF state at a low voltage, they are generally considered as a prevailing candidate for next-generation switch elements.

Most existing TFET designs are based on lateral TFET tunneling. However, lateral TFETs have limited surface area available for electron tunneling. As a result, lateral TFETs have not been able to demonstrate the steep subthreshold slope at drive currents required for mainstream applications.

Recently, vertical TFETs have been developed. An advantage of vertical TFETs is that the vertical TFETs provide a greater tunneling surface area compared to lateral TFETs, and can therefore realize a high ON/OFF state at a low voltage. However, vertical TFETs are difficult to fabricate.

### SUMMARY

The present disclosure is directed to address at least the above deficiencies relating to existing TFET designs.

According to some embodiments of the inventive concept, a field effect transistor is provided. The field effect transistor includes a semiconductor region formed on a substrate, wherein the semiconductor region comprises an undoped channel region, a source region including a first dopant type, and a drain region including a second dopant type, and wherein the channel region is formed of a group III-V compound semiconductor material; a high-K gate formed on the channel region, wherein the high-K gate is configured to generate electron tunneling between the source region and the drain region when a gate voltage is applied; and wherein a first contact surface between the source region and the channel region and a second contact surface between the drain region and the channel region are inclined.

In some embodiments, the field effect transistor may include an n-type field effect transistor, and wherein the group III-V compound semiconductor material may have high electron mobility.

In some embodiments, the field effect transistor may include a p-type field effect transistor, and wherein the group III-V compound semiconductor material may have high hole mobility.

In some embodiments, the group III-V compound semiconductor material may include InSb or GaSb.

In some embodiments, the first dopant type may include acceptor atoms and the second dopant type may include donor atoms.

In some embodiments, the first dopant type may include donor atoms and the second dopant type may include acceptor atoms.

In some embodiments, a doping concentration in each of the source region and the drain region may be equal to or greater than about 1×10¹⁹ cm⁻³.

In some embodiments, the high-K gate may include a gate oxide layer and a metal layer formed on the channel region, and wherein spacers may be disposed on sidewalls of the gate oxide layer and the metal layer.

In some embodiments, a buffer layer may be disposed between the substrate and the semiconductor region.

According to some other embodiments of the inventive concept, a semiconductor device is provided. The semiconductor device includes an n-type field effect transistor and a p-type field effect transistor, wherein each of the n-type and p-type field effect transistors comprises: a semiconductor region formed on a substrate, wherein the semiconductor region comprises an undoped channel region, a source region including a first dopant type, and a drain region including a second dopant type, and wherein the channel region is formed of a group III-V compound semiconductor material; a high-K gate formed on the channel region, wherein the high-K gate is configured to generate electron tunneling between the source region and the drain region when a gate voltage is applied; and wherein a first contact surface between the source region and the channel region and a second contact surface between the drain region and the channel region are inclined; and wherein the semiconductor region of the n-type field effect transistor includes a first semiconductor material having a first conductivity type, and the semiconductor region of the p-type field effect transistor includes a second semiconductor material having a second conductivity type.

In some embodiments, the first semiconductor material may include a group III-V compound semiconductor material having high electron mobility, and the second semiconductor material may include a group III-V compound semiconductor material having high hole mobility.

In some embodiments, the first semiconductor material may include InSb and the second semiconductor material may include GaSb.

In some embodiments, the first dopant type may include acceptor atoms and the second dopant type may include donor atoms.

In some embodiments, the first dopant type may include donor atoms and the second dopant type may include acceptor atoms.

In some embodiments, a doping concentration in each of the source region and the drain region may be equal to or greater than about 1×10¹⁹ cm⁻³.

In some embodiments, the high-K gate may include a gate oxide layer and a metal layer formed on the channel region, and wherein spacers may be disposed on sidewalls of the gate oxide layer and the metal layer.

In some embodiments, a SiGe buffer layer may be disposed between the substrate and the semiconductor region.

According to some further embodiments of the inventive concept, a method of manufacturing a semiconductor device is provided. The method includes forming a semiconductor region on a substrate, wherein the semiconductor region comprises an undoped channel region, a source region including a first dopant type, and a drain region including a second dopant type, and wherein the channel region is formed by epitaxial growth of a group III-V compound semiconductor material on the substrate; forming a high-K gate on the channel region, wherein the high-K gate is configured to generate electron tunneling between the source region and the drain region when a gate voltage is applied; and wherein a first contact surface between the source region and the channel region and a second contact surface between the drain region and the channel region are inclined.

In some embodiments, the method may further include forming a buffer layer between the substrate and the semiconductor region.

In some embodiments, a doping concentration in each of the source region and the drain region may be greater than or equal to 1×10¹⁹ cm⁻³, and the group III-V group compound semiconductor material may include GaSb or InSb.

### BRIEF DESCRIPTION OF THE DRAWINGS

The accompanying drawings, which are incorporated herein and constitute a part of the specification, illustrate different embodiments of the inventive concept and, together with the description, serve to describe more clearly the inventive concept.

It is noted that in the accompanying drawings, for convenience of description, the dimensions of the components shown may not be drawn to scale. Also, same or similar reference numbers between different drawings represent the same or similar components.

FIGS. 1A to 1C depict cross-sectional views of a semiconductor device at different stages of fabrication according to an exemplary method of manufacturing the semiconductor device.

FIGS. 2A to 2I depict cross-sectional views of a semiconductor device at different stages of fabrication according to another exemplary method of manufacturing the semiconductor device.

FIG. 3 is a cross-sectional view of a semiconductor device according to an embodiment of the inventive concept.

FIG. 4A is a schematic diagram of the energy band gap when tunneling in an n-type TFET is blocked.

FIG. 4B is a schematic diagram of the energy band gap when tunneling in an n-type TFET occurs.

FIG. 5A is a schematic diagram of the energy band gap when tunneling in a p-type TFET is blocked.

FIG. 5B is a schematic diagram of the energy band gap when tunneling in a p-type TFET occurs.

### DETAILED DESCRIPTION

Various embodiments of the inventive concept are next described with reference to the accompanying drawings. It is noted that the following description of the different embodiments is merely illustrative in nature, and is not intended to limit the inventive concept, its application, or use. The relative arrangement of the components and steps, and the numerical expressions and the numerical values set forth in these embodiments do not limit the scope of the inventive concept unless otherwise specifically stated. In addition, techniques, methods, and devices as known by those skilled in the art, although omitted in some instances, are intended to be part of the specification where appropriate.

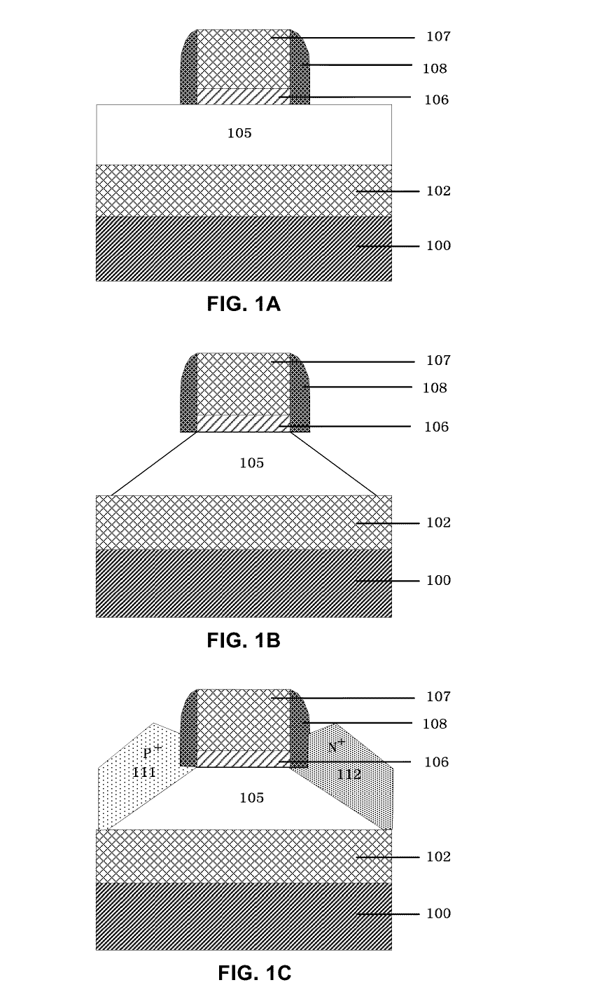

First, a method of manufacturing a semiconductor device according to an embodiment of the inventive concept will be described with reference to FIGS. 1A to 1C. Specifically, FIGS. 1A to 1C depict cross-sectional views of the semiconductor device at different stages of fabrication.

Referring to FIG. 1A, an active region 105 is formed on a substrate 100. The active region 105 may include a group III-V semiconductor material, such as gallium arsenide (GaAs), indium phosphide (InP), gallium nitride (GaN), gallium phosphide (GaP), gallium antimonide (GaSb), indium antimonide (InSb), indium arsenide (InAs), etc. The III-V semiconductor material may be epitaxially grown on the substrate 100, and can be used to form n-type and p-type field effect transistors. The n-type field effect transistors may be formed of III-V compounds having high electron mobility (e.g. InSb), while the p-type field effect transistors may be formed of III-V compounds having high hole mobility (e.g. GaSb).

In some embodiments, a buffer layer 102 may be disposed between the substrate 100 and the active region 105.

Next, a gate structure is formed on the active region 105. The gate structure includes an insulating layer 106 formed on a portion of the active region 105 and a metal gate 107 formed on the insulating layer 106. The insulating layer 106 may include a dielectric material (such as high-k oxide). Spacers 108 are then formed on the sidewalls of the metal gate 107 and the insulating layer 106.

Referring to FIG. 1B, the active region 105 is isotropically etched to form recesses adjacent to the gate structure. As shown in FIG. 1B, the recesses are formed having an undercut beneath the spacers 108. In some embodiments, the buffer layer 102 may serve as an etch stop for the isotropic etching of the active region 105. After the etching, the active region 105 is formed having inclined surfaces between the gate structure and the buffer layer 102. The slope of the inclined surfaces can be adjusted by modifying the etching solution and conditions (such as etching time, temperature, etc.).

Referring to FIG. 1C, a source region 111 and a drain region 112 are formed in the recesses adjacent to the gate structure. As shown in FIG. 1C, the source region 111 is formed on a left inclined surface of the active region 105 and contacts a portion of the left spacer 106; the drain region 112 is formed on a right inclined surface of the active region 105 and contacts a portion of the right spacer 106. The source region 111 may include a first dopant type (e.g. In, and the drain region 112 may include a second dopant type (e.g. N⁺). The source region 111 and drain region 112 may be epitaxially grown in-situ in the recesses. In some embodiments, the dopant concentration in each of the source region 111 and drain region 112 may be greater than 1×10¹⁹ cm⁻³.

With reference to the structure of FIG. 1C, the active region 105 between the source region 111 and the drain region 112 constitutes a channel region. The inclined surfaces between the source/drain regions 111/112 and the channel region increase the surface area available for electron tunneling, thereby improving the performance of the semiconductor device. In some embodiments, the slope of the inclined surfaces can be adjusted by modifying the etching solution and conditions (such as etching time, temperature, etc.), so as to increase or optimize the surface area available for electron tunneling. In addition, the inclined surfaces can be formed relatively easily (compared to the formation of lateral or vertical TFETs), thus allowing greater control over the semiconductor fabrication process.

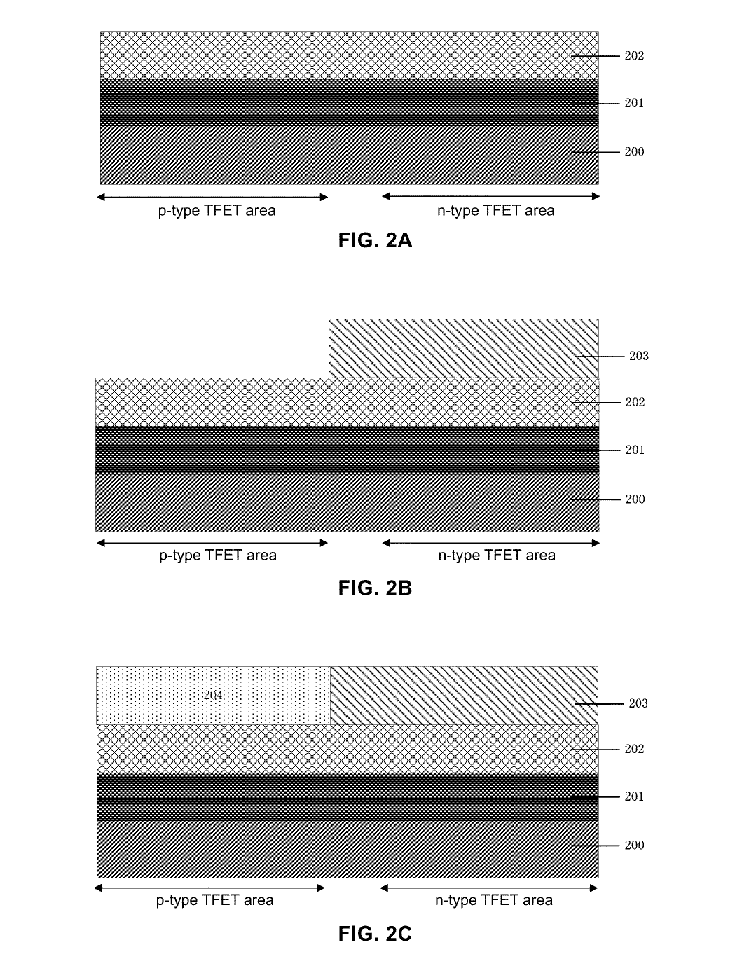

Next, a method of manufacturing a semiconductor device according to another embodiment of the inventive concept will be described with reference to FIGS. 2A to 2I. Specifically, FIGS. 2A to 2I depict cross-sectional views of the semiconductor device at different stages of fabrication.

Referring to FIG. 2A, a SiGe buffer layer 201 is formed on a silicon substrate 200, and an undoped Ge layer 202 is then epitaxially grown on the SiGe buffer layer 201. In some embodiments, a thickness of each of the SiGe buffer layer 201 and the Ge layer 202 may range from about 1 μm to about 5 μm.

Referring to FIG. 2B, an oxide layer (e.g. a silicon dioxide layer) is formed on the Ge layer 202. The oxide layer is then patterned, such that an oxide layer 203 remains in the n-type TFET area.

Referring to FIG. 2C, a GaSb active region 204 is formed on the exposed portion of the Ge layer 202 in the p-type TFET area. The GaSb active region 204 may be formed using MOCVD (Metal Organic Chemical Vapor Deposition), MBE (molecular beam epitaxy), or other similar deposition techniques. In some embodiments, a thickness of the GaSb active region 204 may range from about 10 nm to about 1000 nm.

Referring to FIG. 2D, a nitride layer is formed on the GaSb active region 204 and the oxide region 203. The nitride layer is then patterned, such that a nitride layer 220 remains in the p-type TFET area. Next, the oxide layer 203 is etched using the nitride layer 220 as an etch mask. As shown in FIG. 2D, a portion of the oxide layer 203 remains after the etching. The remaining portion of the oxide layer 203 serves as a STI (Shallow Trench Isolation) and prevents electrical current leakage between adjacent n-type TFETs and p-type TFETs.

Referring to FIG. 2E, an InSb active region 205 is formed on the exposed portion of the Ge layer 202 in the n-type TFET area. The InSb active region 205 may be epitaxially grown on the Ge layer 202 using MOCVD, MBE, etc. In some embodiments, a thickness of the InSb active region 205 may range from about 10 nm to about 1000 nm. After the InSb active region 205 has been formed, the nitride layer 220 is removed.

Referring to FIG. 2F, a high-k oxide layer and a metal layer are formed over the p-type and n-type TFET areas. The high-k oxide layer and the metal layer are then patterned to form a gate structure (comprising a high-k oxide layer 206 and a metal gate 207) on each of the GaSb active region 204 (p-type TFET area) and the InSb active region 205 (n-type TFET area).

Referring to FIG. 2G, spacers 208 are formed on the sidewalls of the gate structures. Specifically, the spacers 208 are formed on the sidewalls of the high-k oxide layer 206 and the metal gate 207 in the respective p-type and n-type TFET areas.

Referring to FIG. 2H, the GaSb active region 204 and the InSb active region 205 are isotropically etched to form recesses adjacent to the gate structures in each region. The isotropic etching may include wet etching. For example, the GaSb active region 204 may be wet etched using HCl:H₂O₂:H₂O in a ratio of 1:1:2; whereas the InSb active region 205 may be wet etched using HF:H₂O₂:H₂O in a ratio of 1:1:4.

As shown in FIG. 2H, the recesses are formed having an undercut beneath the spacers 208. In some embodiments, the buffer layer 202 may serve as an etch stop for the isotropic etching of the active regions 204 and 205. After the etching, the GaSb active region 204 is formed having inclined surfaces between the gate structure (in the p-type TFET area) and the buffer layer 202. Similarly, the InSb active region 205 is formed having inclined surfaces between the gate structure (in the n-type TFET area) and the buffer layer 202. The slope of the inclined surfaces can be adjusted by modifying the etching solution and conditions (such as etching time, temperature, etc.).

Referring to FIG. 2I, a source region 209 and a drain region 210 are formed in the recesses adjacent to the gate structure in the p-type TFET area; and a source region 211 and a drain region 212 are formed in the recesses adjacent to the gate structure in the n-type TFET area. The source region 209 is formed on a left inclined surface of the GaSb active region 204 and contacts a portion of the left spacer 208 in the p-type TFET area. The drain region 210 is formed on a right inclined surface of the GaSb active region 204, and contacts a portion of the right spacer 208 in the p-type TFET area and a left portion of the remaining oxide layer 203 (STI 203). The source region 211 is formed on a left inclined surface of the InSb active region 205, and contacts a right portion of the remaining oxide layer 203 (STI 203) and a portion of the left spacer 208 in the n-type TFET area. The drain region 212 is formed on a right inclined surface of the InSb active region 205 and contacts a portion of the right spacer 208 in the n-type TFET area.

The source regions 209/211 may include a first dopant type (e.g. In, and the drain regions 210/212 may include a second dopant type (e.g., The first dopant type may include Te, and the second dopant type may include Mg or Zn. The source regions 209/211 and the drain regions 210/212 may be epitaxially grown in-situ in the recesses. In some embodiments, the dopant concentration in each of the source regions 209/211 and drain regions 210/212 may be range from about 1×10¹⁹ cm⁻³ to about 5×10¹⁹ cm⁻³. The GaSb active region 204 between the source region 209 and the drain region 210 constitutes a first channel region, and the InSb active region 205 between the source region 211 and the drain region 212 constitutes a second channel region.

In some embodiments, the structure of FIG. 2I may undergo annealing, and the source regions 209/211 and the drain regions 210/212 may be doped after the annealing.

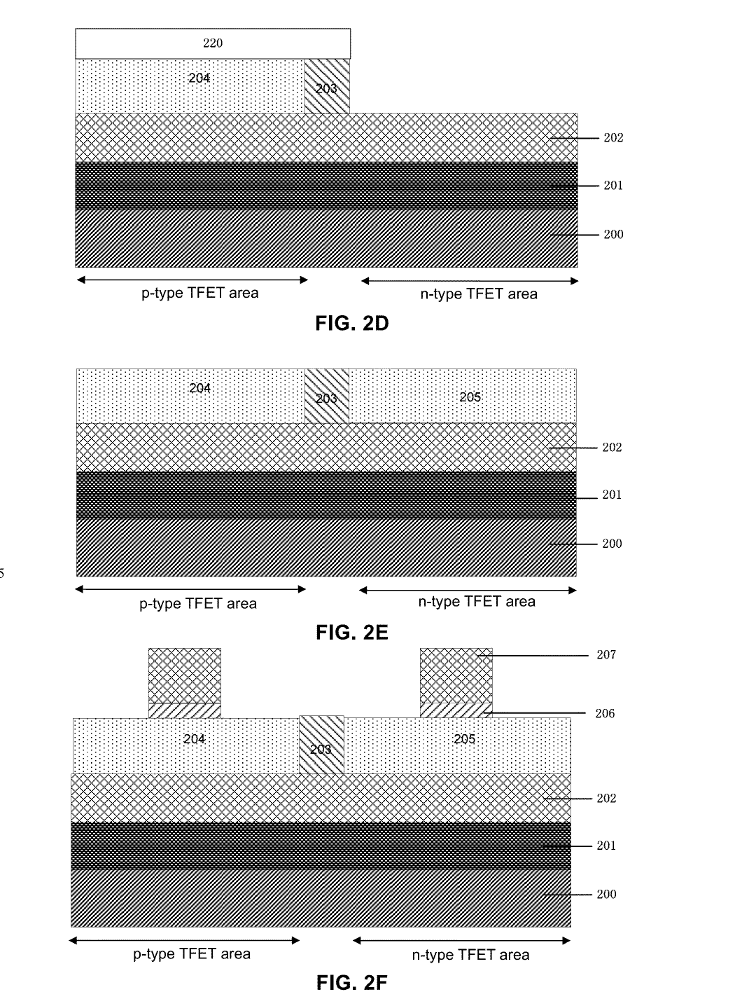

FIG. 3 is a cross-sectional view of a semiconductor device according to an embodiment of the inventive concept.

As shown in FIG. 3, the semiconductor device includes an n-type TFET and a p-type TFET formed on a substrate 300.

The p-type TFET includes an undoped channel region 304, a source region 309 including a first dopant type, and a drain region 310 including a second dopant type.

The n-type TFET includes an undoped channel region 305, a source region 311 including a first dopant type, and a drain region 312 including a second dopant type.

Each of the p-type and n-type TFETs also includes a gate structure comprising an insulating layer 306 and a gate 307. As shown in FIG. 3, spacers 308 are formed on the sidewalls of the respective gate structures.

The channel regions 304/305 may include a group III-V semiconductor material, such as gallium arsenide (GaAs), indium phosphide (InP), gallium (GaN), gallium phosphide (GaP), gallium antimonide (GaSb), indium antimonide (InSb), indium arsenide (InAs), etc. The III-V semiconductor material may be epitaxially grown on the substrate 300, and is used to form the n-type and p-type TFETs. For example, the n-type TFET may be formed of III-V compounds having high electron mobility (e.g. InSb), while the p-type TFET may be formed of III-V compounds having high hole mobility (e.g. GaSb).

With reference to the p-type TFET in FIG. 3, a subthreshold voltage V_{D} is applied to the source region 309, a gate voltage V_{G} is applied to the gale structure, and the drain region 310 is connected to ground (GND). With reference to the n-type TFET in FIG. 3, the source region 311 is connected to ground (GND), a gate voltage V_{G} is applied to the gate structure, and a subthreshold voltage V_{D} is applied to the drain region 312. As shown in FIG. 3, the gate voltages V_{G} of the p-type and n-type TFETs have opposite polarities. Likewise, the subthreshold voltages V_{D} of the p-type and n-type TFETs have opposite polarities.

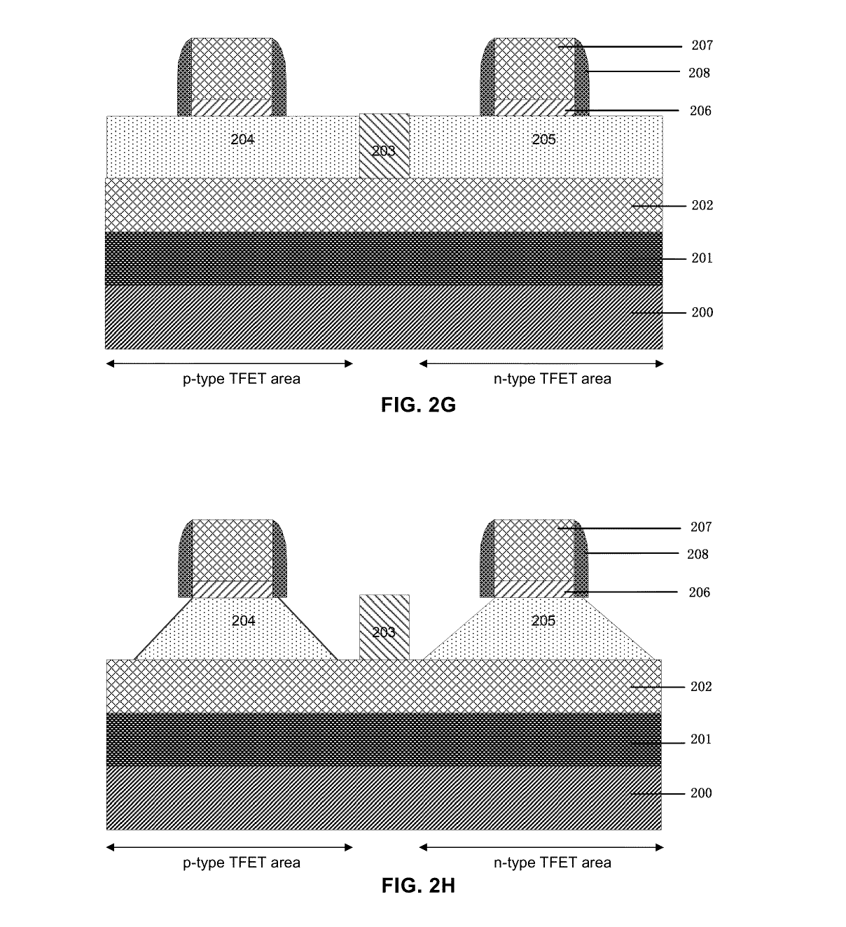

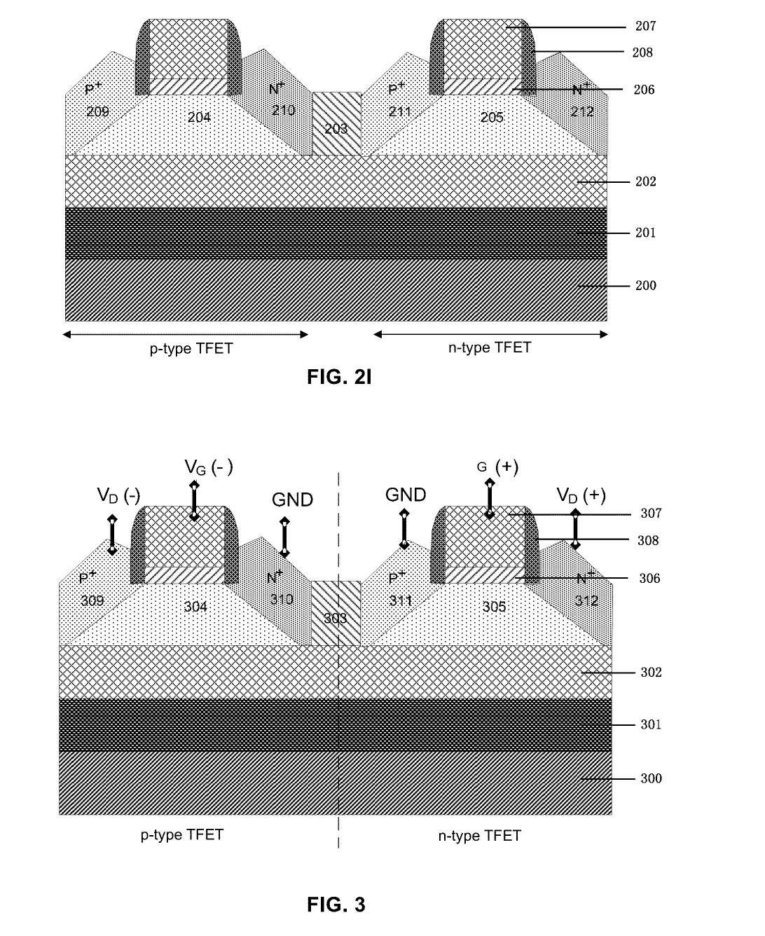

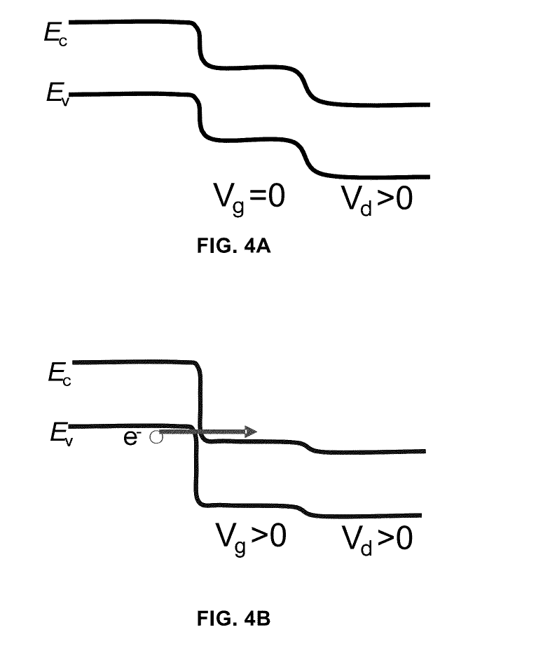

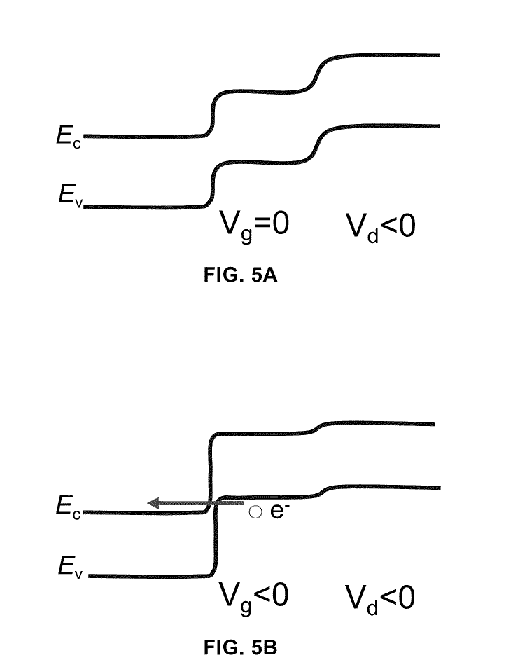

Next, the operation of the n-type TFET in FIG. 3 will be described with reference to FIGS. 4A and 4B, and the operation of the p-type TFET in FIG. 3 will be described with reference to FIGS. 5A and 5B. Specifically, FIG. 4A is a schematic diagram of the energy band gap when tunneling in the n-type TFET is blocked, and FIG. 4B is a schematic diagram of the energy band gap when tunneling in the n-type TFET occurs. Similarly, FIG. 5A is a schematic diagram of the energy band gap when tunneling in the p-type TFET is blocked, and FIG. 5B is a schematic diagram of the energy band gap when tunneling in the p-type TFET occurs.

With reference to FIG. 4A, when the n-type TFET is in an OFF state (V_{G}=0 and V_{D}>0), there is a wide potential barrier between the drain region 312 and the channel region 305, and as a result no tunneling occurs. Accordingly, only a very small leakage current exists.

With reference to FIG. 4B, when the gate voltage V_{G} exceeds the subthreshold voltage V_{D}, the potential barrier between the channel region 305 and the drain region 312 becomes narrow enough to allow a significant tunneling current, which switches the n-type TFET to an ON state. As shown in FIG. 4B, the valence band energy (E_{V}) of the channel region 305 is closer to the conduction band energy (E_{C}) of the drain region 312 when the n-type TFET is in an ON state. Because of the different source carrier injection mechanism in the n-type TFET compared to a conventional MOSFET, the subthreshold voltage V_{D} of the n-type TFET can be reduced to less than 60 mV/dec.

With reference to FIG. 5A, when the p-type TFET is in an OFF state (V_{G}=0 and V_{D}<0), there is a wide potential barrier between the source region 309 and the channel region 304, and as a result no tunneling occurs. Accordingly, only a very small leakage current exists.

With reference to FIG. 5B, when the gate voltage V_{G} decreases below the subthreshold voltage V_{D}, the potential barrier between the channel region 304 and the source region 309 becomes narrow enough to allow a significant tunneling current, which switches the p-type TFET to an ON state. As shown in FIG. 5B, the valence band energy (E_{V}) of the channel region 304 is closer to the conduction band energy (E_{C}) of the source region 309 when the p-type TFET is in an ON state. Because of the different source carrier injection mechanism in the p-type TFET compared to a conventional MOSFET, the subthreshold voltage V_{D} of the p-type TFET can be reduced to less than 60 mV/dec.

In some embodiments, the channel region 304 may be formed of a narrow bandgap semiconductor material having high carrier (hole) mobility (e.g. GaSb), and the channel region 305 may be formed of a narrow bandgap semiconductor material having high carrier (electron) mobility (e.g. InSb).

Next, exemplary methods and processing conditions for the epitaxial growth of the active/channel regions in FIGS. 1-3 will be described. In a conventional MOCVD reactor, Group III elements (e.g. In) and Group V elements (e.g. Sb) are injected into a reaction chamber from a common manifold. The masses and flow rates of the injected gases can be controlled using mass flow controllers.

In some embodiments, GaSb is epitaxially grown (via MOCVD) at a temperature of about 600° C. to about 800° C.; TEGa is used as a source for Ga, and the flow rate of TEGa ranges from about 10 μmol/min to about 100 μmol/min; TMSb is used as a source for Sb, and the flow rate of TMSb ranges from about 10 μmol/min to about 100 μmol/min; the ratio of TMSb to TEGa ranges from about 10 to about 100; Te is used as an n-type dopant; Zn or Mg is used as a p-type dopant; and the process is carried out at a pressure of about 2 Torr to about 100 Torr.

In some embodiments, InSb is epitaxially grown (via MOCVD) at a temperature of about 450° C. to about 600° C.; TMIn is used as a source for In, and the flow rate of TMIn ranges from about 10 μmol/min to about 100 μmol/min; TMSb is used as a source for Sb, and the flow rate of TMSb ranges from about 10 μmol/min to about 100 μmol/min; the ratio of TMSb to TMIn ranges from about 10 to about 100; Te is used as an n-type dopant; Zn or Mg is used as a p-type dopant; and the process is carried out at a pressure of about 2 Torr to about 100 Torr.

A semiconductor device and method of manufacturing the semiconductor device according to different embodiments of the inventive concept have been described above. In order to avoid obscuring the inventive concept, details that are well-known in the art may have been omitted. Nevertheless, those skilled in the art would be able to understand the implementation of the inventive concept and its technical details in view of the present disclosure.

The different embodiments of the inventive concept have been described with reference to the accompanying drawings. However, the different embodiments are merely illustrative and do not limit the scope of the inventive concept. Furthermore, those skilled in the art would appreciate that various modifications can be made to the different embodiments without departing from the scope of the inventive concept.

What is claimed is:

1. A field effect transistor comprising:
a semiconductor region formed on a substrate, wherein the semiconductor region comprises an undoped channel region, a source region including a first dopant type, and a drain region including a second dopant type, and wherein the channel region is formed of a group III-V compound semiconductor material;
a high-K gate formed on the channel region, wherein the high-K gate is configured to generate electron tunneling between the source region and the drain region when a gate voltage is applied; and
wherein a first contact surface between the source region and the channel region and a second contact surface between the drain region and the channel region are inclined.

2. The transistor according to claim 1, wherein the field effect transistor includes an n-type field effect transistor, and wherein the group III-V compound semiconductor material has high electron mobility.

3. The transistor according to claim 1, wherein the field effect transistor includes a p-type field effect transistor, and wherein the group III-V compound semiconductor material has high hole mobility.

4. The transistor according to claim 1, wherein the group III-V compound semiconductor material includes InSb or GaSb.

5. The transistor according to claim 1, wherein the first dopant type includes acceptor atoms and the second dopant type includes donor atoms.

6. The transistor according to claim 1, wherein the first dopant type includes donor atoms and the second dopant type includes acceptor atoms.

7. The transistor according to claim 1, wherein a doping concentration in each of the source region and the drain region is equal to or greater than about 1×10¹⁹ cm⁻³.

8. The transistor according to claim 1, wherein the high-K gate comprises a gate oxide layer and a metal layer formed on the channel region, and wherein spacers are disposed on sidewalls of the gate oxide layer and the metal layer.

9. The transistor according to claim 1, wherein a buffer layer is disposed between the substrate and the semiconductor region.

10. A semiconductor device, comprising:
an n-type field effect transistor and a p-type field effect transistor, wherein each of the n-type and p-type field effect transistors comprises:
a semiconductor region formed on a substrate, wherein the semiconductor region comprises an undoped channel region, a source region including a first dopant type, and a drain region including a second dopant type, and wherein the channel region is formed of a group III-V compound semiconductor material;
a high-K gate formed on the channel region, wherein the high-K gate is configured to generate electron tunneling between the source region and the drain region when a gate voltage is applied; and
wherein a first contact surface between the source region and the channel region and a second contact surface between the drain region and the channel region are inclined; and
wherein the semiconductor region of the n-type field effect transistor includes a first semiconductor material having a first conductivity type, and the semiconductor region of the p-type field effect transistor includes a second semiconductor material having a second conductivity type.

11. The semiconductor device according to claim 10, wherein the first semiconductor material includes a group III-V compound semiconductor material having high electron mobility, and the second semiconductor material includes a group III-V compound semiconductor material having high hole mobility.

12. The semiconductor device according to claim 10, wherein the first semiconductor material includes InSb and the second semiconductor material includes GaSb.

13. The semiconductor device according to claim 10, wherein the first dopant type includes acceptor atoms and the second dopant type includes donor atoms.

14. The semiconductor device according to claim 10, wherein the first dopant type includes donor atoms and the second dopant type includes acceptor atoms.

15. The semiconductor device according to claim 10, wherein a doping concentration in each of the source region and the drain region is equal to or greater than about 1×10¹⁹ cm⁻³.

16. The semiconductor device according to claim 10, wherein the high-K gate comprises a gate oxide layer and a metal layer formed on the channel region, and wherein spacers are disposed on sidewalls of the gate oxide layer and the metal layer.

17. The semiconductor device according to claim 9, wherein a SiGe buffer layer is disposed between the substrate and the semiconductor region

18. A method of manufacturing a semiconductor device, comprising:
forming a semiconductor region on a substrate, wherein the semiconductor region comprises an undoped channel region, a source region including a first dopant type, and a drain region including a second dopant type, and wherein the channel region is formed by epitaxial growth of a group III-V compound semiconductor material on the substrate;
forming a high-K gate on the channel region, wherein the high-K gate is configured to generate electron tunneling between the source region and the drain region when a gate voltage is applied; and
wherein a first contact surface between the source region and the channel region and a second contact surface between the drain region and the channel region are inclined.

19. The method according to claim 18, further comprising:
forming a buffer layer between the substrate and the semiconductor region.

20. The method according to claim 19, wherein a doping concentration in each of the source region and the drain region is greater than or equal to 1×10¹⁹ cm⁻³, and the group III-V group compound semiconductor material includes GaSb or InSb.
